(19) United States
(12) Patent Application Publication
(10) Pub. No.: US 2017/0226378 A1
(43) Pub. Date: Aug. 10, 2017

(54) Method for Manufacturing an Optical Semiconductor Device and a Silicone Resin Composition Therefor

(71) Applicants: Henkel IP & Holding GmbH, Duesseldorf (DE); Henkel AG & Co. KGaA, Duesseldorf (DE)

(72) Inventors: Aya Hikita, Kanagawa (JP); Qingxu Yang, Shanghai (CN); George Henry Temme, Cheshire, CT (US); Kevin Becker, Cerritos, CA (US); Kazuya Nagao, Kanagawa (JP)

(21) Appl. No.: 15/497,773

(22) Filed: Apr. 26, 2017

Related U.S. Application Data
(63) Continuation of application No. PCT/CN2014/089532, filed on Oct. 27, 2014.

(51) Int. Cl. C09D 183/04; C08L 83/04; H01L 33/62; C09D 5/33; H01L 33/60; H01L 33/56

(52) U.S. Cl. CPC C09D 183/04; H01L 33/60; H01L 33/56; H01L 33/62; C09D 5/004; C08L 83/04; H01L 2933/0033; H01L 2933/005; H01L 2933/0058; H01L 2933/0066; C08L 2203/20; C08L 2205/025

(57) ABSTRACT

The present invention relates to a method for manufacturing an optical semiconductor device, particularly an LED device, and to a silicone resin composition suitable for using in the method.

### TECHNICAL FIELD

The present invention relates to a method for manufacturing an optical semiconductor device, particularly an LED device, and to a silicone resin composition suitable for using in the method.

### BACKGROUND

An optical semiconductor device such as a light emitting diode (LED) device has now been widely used as various indicators or light sources for such as exterior illumination, automobile lamp and home lighting due to their low power consumption, high efficiency, quick reaction time, long life and the absence of toxic elements such as mercury in the manufacturing process.

Conventionally, such an optical semiconductor device is in a form of package, and comprises a substrate having electric circuit, an optical semiconductor chip amounted on the substrate, reflectors surrounding at least part of the optical semiconductor chip, and an encapsulant enclosing the optical semiconductor chip.

Molding is the most commonly used technology to form a reflector for the optical semiconductor devices. In particular, various molding methods, including injection molding, transfer molding and compression molding has been widely used in the art for forming the reflector made from resinous materials.

For example, US 20130274398 A discloses a thermosetting silicone resin composition for the reflector of LED, and further teaches that the reflectors for an LED therein may be formed by transfer molding or compression molding.

U.S. Pat. No. 8,466,483 A discloses an epoxy resin composition for forming the reflector of an optical semiconductor device. In the manufacturing process, the reflector is produced by transfer molding.

JP 2002283498 A discloses a reflector of an optical semiconductor device formed by the injection molding of a thermoplastic resin represented by a polyphthalamide resin or the like.

However, the molding methods has drawbacks including high manufacturing cost due to the initial investment to prepare the mold, slow production speed and the waste of reflector material.

Printing methods has been proposed in the art for replacing molding methods for forming a reflector of an optical semiconductor device, since printing methods only requires a traditional printer and will bring about lower initial investment cost, faster production speed and less waste of the reflector material compared to the molding methods.

For example, JP 2014057090 A discloses that in the manufacturing process of an optical semiconductor device, the reflector can be formed by screen printing to improve the adhesion between the substrate and reflector material. However, the reflector and package are individually and separately formed therein, so that such manufacturing process still has a drawback of low production speed and the waste of the reflector material.

Therefore, it is the object of the present invention to develop an improved manufacturing method of an optical semiconductor device which can overcome at least one of these challenges. Also, it is another object of the present invention to develop a silicone resin composition suitable for using in the manufacturing method, especially for screen printing. These problems are solved by the disclosed subject matters.

### SUMMARY OF THE INVENTION

One aspect discloses a method for manufacturing an optical semiconductor device, comprising the steps of:
1) providing a substrate consisting of more than one substrate unit each having an electrical circuit;
2) providing a silicone resin composition for reflector on each substrate unit by a printing process;
3) curing the silicone resin composition for reflector, and obtaining a reflector which defines a cavity on each substrate unit;
4) attaching an optical semiconductor chip on each substrate unit in each cavity, and electrically connecting each optical semiconductor chip to each electrical circuit on the substrate unit;
5) providing an encapsulant in each cavity, curing, and obtaining each optical semiconductor device; and
6) dicing the optical semiconductor devices by a cutting device to obtain individual optical semiconductor devices.

Another aspect of the present invention discloses a silicone resin composition suitable for using in the method, comprising:
a) a silicone resin containing at least two alkenyl group reactive with a Si—H group per molecule,
b) a silicone resin containing at least two Si—H groups per molecule,
c) a white pigment, preferably selected from the group consisting of titanium oxide, zinc oxide, magnesium oxide, barium carbonate, magnesium silicate, zinc sulfate, barium sulfate, and the combination thereof,
d) a hydrosilylation catalyst, and
e) an inorganic filler.

Yet another aspect discloses an optical semiconductor device manufactured by the method according to the present invention.

Other features and aspects of the subject matter are set forth in greater detail below.

### BRIEF DESCRIPTION OF THE DRAWINGS

Exemplary embodiments of the present invention will be readily understood with reference to the following detailed description thereof provided in conjunction with the accompanying drawings, wherein like reference numerals designate like structural elements.

FIGS. 1 to 3 are cross-sectional views of a method for manufacturing LED chip devices according to an exemplary embodiment of the present invention;

FIG. 4 is a cross-sectional view of one example of a LED device manufactured by the method according to the present invention;

FIG. 5 is a cross-sectional view of another example of a LED device manufactured by the method according to the present invention;

FIG. 6 is a top view of the substrate used in the manufacturing method according to the present invention; and

FIG. 7 is a cross-sectional view of the partially molded LED devices manufactured by the method according to a conventional method.

The drawings are provided for illustrative purposes only and are not drawn to scale. The spatial relationships and relative sizing of the illustrated elements may be reduced, expanded or rearranged to improve the clarity of the figures with respect to the corresponding description. The figures, therefore, may not accurately reflect the relative sizing or positioning of the corresponding structural elements that could be encompassed by an actual device manufactured according to the exemplary embodiments of the invention.

### DETAILED DESCRIPTION

It is to be understood by one of ordinary skill in the art that the present discussion is a description of exemplary embodiments only, and is not intended as limiting the broader aspects of the present invention.

In one aspect, the present disclosure is generally directed to a method for manufacturing an optical semiconductor device, comprising the steps of:
1) providing a substrate consisting of more than one substrate unit each having an electrical circuit;
2) providing a silicone resin composition for reflector on each substrate unit by a printing process;
3) curing the silicone resin composition for reflector, and obtaining a reflector which defines a cavity on each substrate unit;
4) attaching an optical semiconductor chip on each substrate unit in each cavity, and electrically connecting each optical semiconductor chip to each electrical circuit on the substrate unit;
5) providing an encapsulant in each cavity, curing, and obtaining each optical semiconductor device; and
6) dicing the optical semiconductor devices by a cutting device to obtain individual optical semiconductor devices.

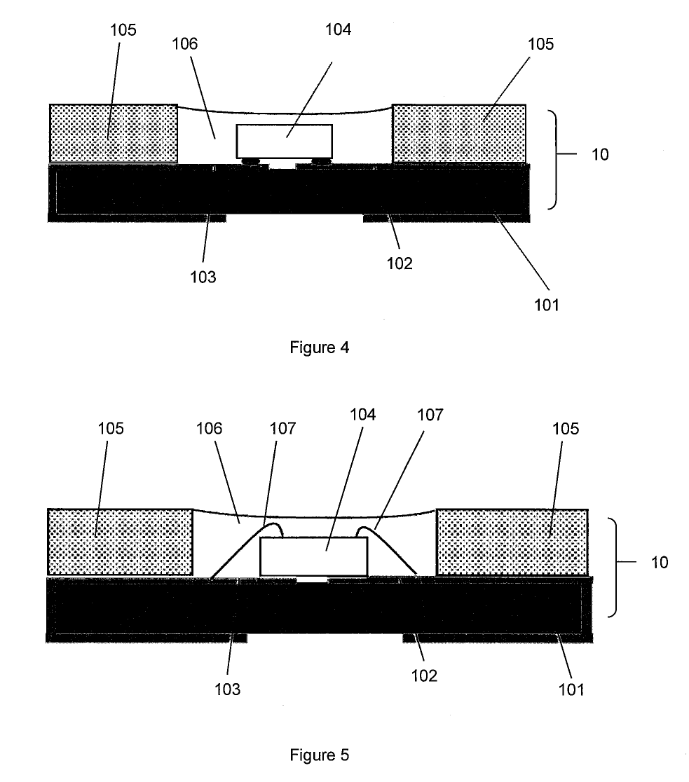

In step 1), a substrate consisting of more than one substrate unit 101 each having an electrical circuit is provided. In one embodiment, the substrate may be formed from the materials including, but not limited to glass, epoxy resin, ceramic, metal, polyimide film, TAB and silicon. Preferably, the substrate is made of ceramic or silicon. The substrate may be divided into several substrate units by the dicing process in step 6) as described below. On each of the substrate units, a circuit is included on the top and back of the substrate unit, constituting a circuit pattern. Each circuit has a first electrode and a second electrode, as shown in FIGS. 4 and 5, which can be connected to the optical semiconductor chip in the step 4) described later.

In step 2) of the present manufacturing method, a silicone resin composition for reflector is provided on each substrate unit by a printing process. Preferably, a silicone resin composition for reflector as described below in details is used. In one embodiment, the printing process is selected from screen printing, stencil printing and offset printing. Preferably, the printing process is screen printing process.

In one embodiment, the screen printing process is conducted by placing a mask having through holes on more than one substrate unit, and squeezing the silicone resin composition for reflector into each through hole. It is understood that the number of the through holes for each substrate unit will depend on the practical need and the design of the optical semiconductor device. Typically, as exemplified in FIGS. 1 to 3, in each unit of optical semiconductor device of the present invention, two through holes are arranged on each substrate unit.

The more than one substrate unit may form an array of substrate unit corresponding to the optical semiconductor devices to be manufactured in a mass production, and thus further forms an array of optical semiconductor devices by using a screen printing mask having an array of through holes.

As used herein, “an array of” refers to that the units of substrate, chip, through hole, reflector, etc. constitute a two dimensional array or matrix having “m” lines and “n” columns, represented by a m×n array, in which “m” and “n” each represents a integer of from 1 to 100, preferably from 2 to 50. For example, with respect to a rectangle form of substrate having a 3×4 array units, a screen printing mask having a 3×4 array of through hole units containing 2 through holes in each unit is used, and thus totally 24 reflectors surrounding 12 chips each electrically connecting to a circle are produced on 12 substrate units.

In step 3) of the manufacturing method according to the present invention, the silicone resin composition for reflector are cured, and thus a reflector which defines a cavity on each substrate unit are obtained.

In one embodiment of the present invention, the silicone resin composition for reflector is cured at a temperature of from 120 to 180° C., preferably from 140 to 160° C. for 10 minutes to 2 hours, preferably 30 minutes to 1.5 hours. Suitable sources of heat to cure the silicone resin composition the present invention include induction heating coils, ovens, hot plates, heat guns, IR sources including lasers, microwave sources, etc.

In another embodiment of the present invention, the reflector after curing has a light reflectance of more than 70%, preferably more than 80% at the wavelength from 350 nm to 800 nm, so that the light emitted by the optical semiconductor chip, for example, an LED chip can be collected, and thus increasing the efficiency of LED device.

In yet another embodiment of the present invention, the height of the reflector is in the range of from 0.1 mm to 3.0 mm, preferably from 0.3 mm to 2.0 mm. If the reflector height is lower than 0.1 mm, it will be difficult to obtain sufficient brightness and luminous efficiency of the optical semiconductor device. If the reflector height is larger than 3.0 mm, the reflector will not reach the height of the chip (die) conventional used in the art, and the chip will not been fully covered by the reflector, partially exposing to the environment after the encapsulation.

In step 4) of the manufacturing method according to the present invention, an optical semiconductor chip is attached on each substrate unit in each cavity, and each optical semiconductor chip is electrically connected to each electrical circuit on the substrate unit.

Referring to FIGS. 4 and 5, the circuit comprises a top surface and a bottom surface opposite to each other, wherein the first electrode 102 comprises a top face and a bottom face, and the second electrode 103 comprises a top face and a bottom face. The first electrode 102 and the second electrode 103 are separated.

Although an optical semiconductor chip is preferably used in which a semiconductor such as GaAlN, ZnS, SnSe, SiC, GaP, GaAlAs, AlN, InN, AlInGaP, InGaN, GaN or AlInGaN is formed on a substrate as a light emitting layer, the semiconductor is not limited to these. Although the light emitting element which provides a light emission peak wavelength between 360 nm and 520 nm is preferable, and a light emitting element which provides a light emission peak wavelength between 350 nm and 800 nm can be used. More preferably, the optical semiconductor chip has the light emission peak wavelength in the short wavelength region of visible light between 420 nm and 480 nm.

In one embodiment, the surface of the optical semiconductor chip attached on each substrate unit is facing upward, and thus the optical semiconductor chip is located on the top face of the first electrode 102 and is electrically connected to the first and the second electrodes 102, 103 via wire leads 107 as shown in FIG. 5. Alternatively, the surface of the optical semiconductor chip attached on each substrate unit is facing downward, and thus the electrical connection can also be achieved by flip chip or eutectic as shown in FIG. 4.

The size of the optical semiconductor chip is not particularly limited, and light emitting elements having sizes of 350 μm (350-μm-square), 500 μm (500-μm-square) and 1 mm (1-mm-square) can be used. Further, a plurality of light emitting elements can be used, and all of the light emitting elements may be the same type or may be different types which emit emission colors of red, green and blue of three primary colors of light.

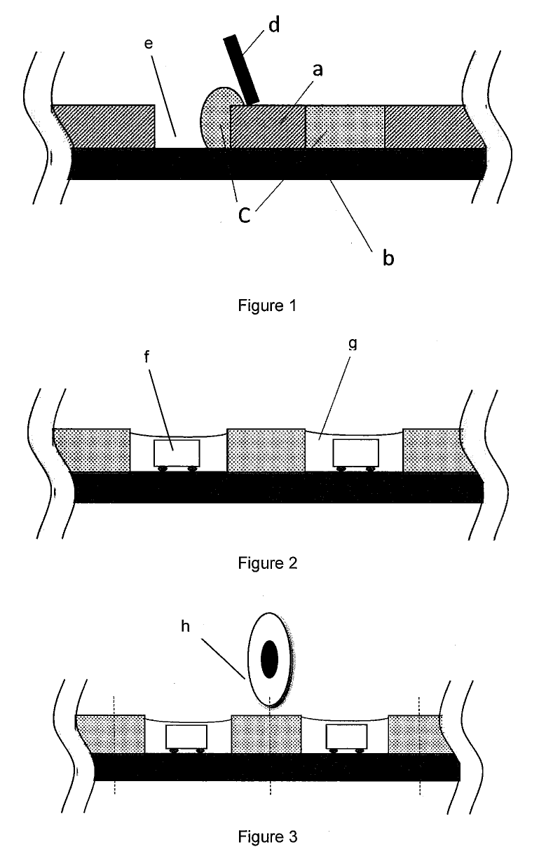

In step 5) of the manufacturing method according to the present invention, as shown in FIG. 2, an encapsulant is provided in each cavity, cured, and thus each optical semiconductor device is obtained.

According to the present invention, the encapsulant is preferably formed from a thermosetting resin. The encapsulant is preferably made of at least one selected from the group consisting of an epoxy resin, modified epoxy resin, silicone resin, modified silicone resin, acrylate resin and urethane resin of a thermosetting resin, and is more preferably made of an epoxy resin, modified epoxy resin, silicone resin or modified silicone resin. The encapsulant is preferably made of a hard material to protect the light emitting element. Further, it is preferable to use a resin having good thermal resistance, weather resistance and light resistance. To provide a predetermined function, the encapsulant may be mixed with at least one selected from the group consisting of filler, diffusing agent, pigment, fluorescent material and reflecting material. The encapsulant may contain a diffusing agent. As a specific diffusing agent, for example, barium titanate, titanium oxide, aluminum oxide or silicon oxide is adequately used. Further, the encapsulant can contain an organic or inorganic colored dye or colored pigment in order to cut an undesirable wavelength. Further, the encapsulant can also contain a fluorescent material which absorbs light from the light emitting element and converts the wavelength. In one embodiment, the encapsulant comprises silicone resin, filler and phosphor.

The filler may include, for example, fine powder silica, fine powder alumina, fused silica, crystalline silica, cristobalite, alumina, aluminum silicate, titanium silicate, silicon nitride, aluminum nitride, boron nitride and antimony trioxide. Moreover, it is also possible to use a fibrous filler such as glass fiber and wollastonite.

The fluorescent material may be a material which absorbs light from the light emitting element, and converts the wavelengths into light of a different wavelength. The fluorescent material is preferably selected from, for example, at least any one of a nitride phosphor, oxynitride phosphor or sialon phosphor mainly activated by a lanthanoid element such as Eu or Ce, alkaline-earth halogen apatite phosphor, alkaline-earth metal boric acid halogen phosphor, alkaline-earth metal aluminate phosphor, alkaline-earth silicate, alkaline-earth sulfide, alkaline-earth thiogallate, alkaline-earth silicon nitride or germanate mainly activated by a lanthanoid element such as Eu or a transition metal such as Mn, rare-earth aluminate or rare-earth silicon nitride mainly activated by a lanthanoid element such as Ce, or organic and organic complexes mainly activated by a lanthanoid element such as Eu. As a specific example, although the following phosphors can be used, the fluorescent material is not limited to these.

The nitride phosphor mainly activated by a lanthanoid element such as Eu or Ce includes, for example, M₂Si₅N₈:Eu or MAISiN₃:Eu (where M is at least one or more selected from Sr, Ca, Ba, Mg and Zn). Further, the nitride phosphor also includes MSi₇N₁₀:Eu, M_{1.8}Si₅O_{0.2}N₈:Eu or M_{0.9}Si₇O_{0.1}N₁₀:Eu in addition to M₂Si₅N₈:Eu (where M is at least one or more selected from Sr, Ca, Ba, Mg and Zn).

The oxynitride phosphor mainly activated by a lanthanoid element such as Eu or Ce includes, for example, MSi₂O₂N₂:Eu (where M is at least one or more selected from Sr, Ca, Ba, Mg and Zn).

The sialon phosphor mainly activated by a lanthanoid element such as Eu or Ce includes, for example, M_{p/2}Si_{12-p-q}Al_{p+q}O_{q}N₁₆₋ₚ:Ce or M—Al—Si—O—N (M is at least one selected from Sr, Ca, Ba, Mg and Zn, q is 0 to 2.5, and p is 1.5 to 3).

The alkaline-earth halogen apatite phosphor mainly activated by a lanthanoid element such as Eu or a transition metal such as Mn includes, for example, M₅(PO₄)₃X:R (M is at least one or more selected from Sr, Ca, Ba, Mg and Zn, X is at least one or more selected from F, Cl, Br and I, and R is at least one or more selected from Eu, Mn, Eu and Mn).

The alkaline-earth metal boric acid halogen phosphor includes, for example, M₂B₅O₉X:R (M is at least one or more selected from Sr, Ca, Ba, Mg and Zn, X is at least one or more selected from F, Cl, Br and I, and R is at least one or more selected from Eu, Mn, Eu and Mn).

The alkaline-earth metal aluminate phosphor includes, for example, SrAl₂O₄:R, Sr₄Al₁₄O₂₅:R, CaAl₂O₄:R, BaMg₂Al₁₆O₂₇:R, BaMg₂Al₁₆O₁₂:R, or BaMgAl₁₀O₁₇:R(R is at least one or more selected from Eu, Mn, Eu and Mn).

The alkaline-earth sulfide phosphor includes, for example, La₂O₂S:Eu, Y₂O₂S:Eu or Gd₂O₂S:Eu.

The rare-earth aluminate phosphor mainly activated by a lanthanoid element such as Ce includes, for example, YAG phosphors represented by composition formulae of Y₃Al₅O₁₂:Ce, (Y_{0.8}Gd_{0.2})₃Al₅O₁₂:Ce, Y₃(Al_{0.8}Ga_{0.2})₅O₁₂:Ce and (Y,Gd)₃(Al,Ga)₅O₁₂:Ce. Further, the rare-earth aluminate phosphor also includes Tb₃Al₅O₁₂:Ce or Lu₃Al₅O₁₂:Ce where part or all of Y is substituted with, for example, Tb or Lu.

The other phosphors include, for example, ZnS:Eu, Zn₂GeO₄:Mn or MGa₂S₄:Eu (where M is at least one or more selected from Sr, Ca, Ba, Mg and Zn).

By using one kind alone or two or more kinds in combination, these phosphors can realize blue, green, yellow and red and, in addition, tinges such as turquoise, greenish yellow and orange which are intermediate colors of blue, green, yellow and red.

The curing process for the encapsulant in step 5) is achieved at a temperature of from 120 to 180° C., preferably from 140 to 160° C. for 1 to 10 hours, preferably 2 minutes to 8 hours. Suitable sources of heat to cure the silicone resin composition include induction heating coils, ovens, hot plates, heat guns, IR sources including lasers, microwave sources, etc.

In step 6) of the manufacturing method according to the present invention, as shown in FIG. 3, the optical semiconductor devices are diced by a cutting device to obtain individual optical semiconductor devices. For example, the cutting device is a rotary blade. After the dicing process, optical semiconductor devices are optionally cleaned and dried. The optical semiconductor devices thus obtained have high product-dimensional accuracy and cause less waste of the reflector material.

It is understood that the sequence of at least part of steps is not limited, and may be altered according to the practical need by a person skilled in the art. For example, the screen printing of the reflector material may be conducted before or after providing the optical semiconductor chip on each substrate unit. Therefore, in one embodiment, the present invention provides a method for manufacturing an optical semiconductor device, comprising the steps of, in this sequence: steps 1) through 6). In other embodiment, the present invention provides a method for manufacturing an optical semiconductor device, comprising the steps of, in this sequence: steps 1), 4), 2), 3), 5) and 6).

Another aspect of the present invention is the optical semiconductor device manufactured by the method according to the present invention.

As illustrated in FIG. 4, the optical semiconductor device 10 comprises a substrate 101, a circuit having a first electrode 102 and a second electrode 103 on the substrate 101, reflectors 105, an optical semiconductor chip 104 in a flip chip form, and an encapsulant 106.

As illustrated in FIG. 5, the optical semiconductor device 10 comprises a substrate 101, a circuit having a first electrode 102 and a second electrode 103 on the substrate 101, reflectors 105, an optical semiconductor chip 104, wire leads 107 electrically connecting the chip to the electrodes, and an encapsulant 106.

Another aspect of the present invention is the silicone resin composition for reflector suitable for using in the manufacturing method. The silicone resin composition comprises:
a) a silicone resin containing at least two alkenyl groups reactive with a Si—H group per molecule,
b) a silicone resin containing at least two Si—H groups per molecule,
c) a white pigment,
d) a hydrosilylation catalyst, and
e) an inorganic filler, wherein each component is present in the amount specified below and in the claims.

Surprisingly, the inventors found that the silicone resin compositions according to the present invention possess an excellent viscosity and thixotropic property so that they are suitable for printing process for forming the reflector of optical semiconductor devices.

### Component a)

The silicone resin composition for reflector comprises a silicone resin containing at least two alkenyl groups reactive with a Si—H group per molecule as component a).

In one embodiment, the component a) is represented by the average compositional formula (1):

(R¹R²R³SiO_{1/2})ₐ(R⁴R⁵SiO_{2/2})_{b}(R⁶SiO_{3/2})_{c}(SiO_{4/2})_{d} (1),

in which,
R¹ to R⁶ are identical or different groups independently selected from the group consisting of organic groups and an alkenyl group, with the proviso that at least one of R¹ to R⁶ is an alkenyl group,
a represents a number ranging from larger than 0 to less than 1, b, c and d each represent a number ranging from 0 to less than 1, a+b+c+d =1.0, and the number of alkenyl groups per molecule of the silicone resin is at least 2.

In the above-mentioned average compositional formula (1), the organic groups for R¹ to R⁶ are preferably selected from the group consisting of linear or branched alkyl groups having 1 to 20 carbon atoms, alkenyl groups having 2 to 20 carbon atoms, cycloalkyl groups having 5 to 25 carbon atoms, cycloalkenyl groups having 5 to 25 carbon atoms, aryl groups having 6 to 30 carbon atoms, arylalkyl groups having 7 to 30 carbon atoms, and halides of said alkyl, alkenyl, cycloalcyl, cycloalkenyl, aryl and arylalkyl groups.

The term “halides” used in the present invention refers to one or more halogen-substituted hydrocarbyl groups represented by R¹ to R⁶. The term “halogen-substituted” refers to fluoro-, chloro-, bromo- or iodo-radicals.

Still more preferably, said organic groups are selected from the group consisting of linear or branched alkyl groups having 1 to 10 carbon atoms, alkenyl groups having 2 to 10 carbon atoms, cycloalkyl groups having 5 to 15 carbon atoms, cycloalkenyl groups having 5 to 15 carbon atoms, aryl groups having 6 to 15 carbon atoms, arylalkyl groups having 7 to 15 carbon atoms, and fluorides or chlorides thereof. Still particularly preferably, said organic groups are selected from the group consisting of alkyl groups having 1 to 3 carbon atoms and phenyl. Alkyl groups having 1 to 3 carbon atoms can be methyl, ethyl, n-propyl and i-propyl.

As used herein, the structure of (R¹R²R³SiO_{1/2})a(R⁴R⁵SiO_{2/2})b(R⁶SiO_{3/2})c(SiO_{4/2})d can be identified with reference to certain units contained in a silicone resin structure; These units have been designated as M, D, T and Q units, which represent, respectively, units with the empirical formulae R¹R²R³SiO_{1/2}, R⁴R⁵SiO_{2/2}, R⁶SiO_{3/2} and SiO_{4/2}, wherein each of R¹ to R⁶ represents a monovalent substituent as defined above. The letter designations M, D, T and Q refer respectively, to the fact that the unit is monofunctional, difunctional, trifunctional or tetrafunctional. The units of M, D, T and Q are arranged randomly or in blocks. For example, blocks of units of M, D, T and Q may follow one another, but the individual units may also be linked in random distribution, depending upon the siloxane used during preparation.

In one embodiment, the component a) comprises an alkenyl functional MD silicone resin represented by formula (2) and an alkenyl functional QM resin represented by formula (3):

(R⁷R⁸R⁹SiO_{1/2})ₑ(R¹⁰R¹¹SiO_{2/2})_{f} (2),

in which,
R⁷ to R¹¹ are identical or different groups independently selected from the group consisting of organic groups and an alkenyl group, with the proviso that at least one of R⁷ to R¹¹ is an alkenyl group,
e and f each represent a number ranging from larger than 0 to less than 1, e+f =1.0, and
the number of alkenyl group per molecule of the alkenyl functional MD silicone resin is at least 2;

(R¹²R¹³R¹⁴SiO_{1/2})_{g}(SiO_{4/2})ₕ (3),

in which,
R¹² to R¹⁴ are identical or different groups independently selected from the group consisting of organic groups and an alkenyl group, with the proviso that at least one of R¹² to R¹⁴ is an alkenyl group,
g and h each represent a number ranging from larger than 0 to less than 1, g+h=1.0, and the number of alkenyl group per molecule of the alkenyl functional MQ silicone resin is at least 2.

Suitable example of the alkenyl functional MD silicone resin may be silicone resin represented by formula (4):

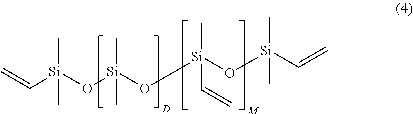

wherein, D is a number of 1 to 100, preferably 1 to 50, and M is a number of 1 to 100, preferably 1 to 50.

In one embodiment, the alkenyl content of component a) is ranging from 0.3 mmole/g to 0.5 mmole/g.

In one embodiment, the weight ratio of the alkenyl functional MD silicone resin to the alkenyl functional MQ silicone resin is ranging from 0.5:9.5 to 9:1, preferably from 1:9 to 6:4.

Such silicone resins for component a) can be purchased for example from AB Specialty Silicones under the trade name of Andisil VQM 0.6, VQM 0.8, VQM 1.0 and VQM 1.2. While the silicone resins are commercially available, methods for synthesizing such silicone resins are well known in the art.

The component (a) is present in an amount of from 18% to 35%, preferably from 22% to 33% by weight of the total weight of all components.

### Component b)

The silicone resin composition for reflector comprises a silicone resin containing at least two Si—H groups per molecule as component b).

In one embodiment, the component b) is represented by the average compositional formula (5):

(R¹R²R³SiO_{1/2})ₐ(R⁴R⁵SiO_{2/2})_{b}(R⁶SiO_{3/2})_{c}(SiO_{4/2})_{d} (5),

in which,
R¹ to R⁶ are identical or different groups independently selected from the group consisting of organic groups and hydrogen atom bonded directly to a silicon atom, with the proviso that at least one of R¹ to R⁶ is a hydrogen atom bonded directly to a silicon atom,
a and d each represent a number ranging from larger than 0 to less than 1, b and c each represent a number ranging from 0 to less than 1, a+b+c+d=1.0, and the number of hydrogen atom bonded directly to a silicon atom per molecule of the silicone resin is at least 2.

In the above-mentioned average compositional formula (5), the organic groups for R¹ to R⁶ are preferably selected from the group consisting of linear or branched alkyl groups having 1 to 20 carbon atoms, alkenyl groups having 2 to 20 carbon atoms, cycloalkyl groups having 5 to 25 carbon atoms, cycloalkenyl groups having 5 to 25 carbon atoms, aryl groups having 6 to 30 carbon atoms, arylalkyl groups having 7 to 30 carbon atoms, and halides of said alkyl, alkenyl, cycloalcyl, cycloalkenyl, aryl and arylalkyl groups.

Still more preferably, said organic groups are selected from the group consisting of linear or branched alkyl groups having 1 to 10 carbon atoms, alkenyl groups having 2 to 10 carbon atoms, cycloalkyl groups having 5 to 15 carbon atoms, cycloalkenyl groups having 5 to 15 carbon atoms, aryl groups having 6 to 15 carbon atoms, arylalkyl groups having 7 to 15 carbon atoms, and fluorides or chlorides thereof. Still particularly preferably, said organic groups are selected from the group consisting of alkyl groups having 1 to 3 carbon atoms and phenyl. Alkyl groups having 1 to 3 carbon atoms can be methyl, ethyl, n-propyl and i-propyl.

In one embodiment, component a) is preferably selected from the silicone resins represented by formula (6):

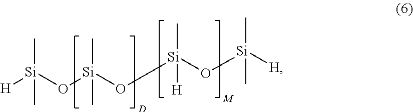

wherein D is a number of 1 to 100, preferably 1 to 50, and M is a number of 1 to 100, preferably 1 to 50.

Such silicone resins containing Si—H groups are commercially available under the trade name of Syl-Off® 7672, 7048, and 7678 from Dow Corning Company.

While the silicone resins are commercially available, methods for synthesizing such silicone resins are well known in the art.

The component b) is present in an amount of from 1.5% to 2.7%, preferably from 1.7% to 2.5% by weight of the total weight of all components.

### Component c)

In addition, the silicone resin composition for reflector comprises a white pigment, preferably selected from the group consisting of titanium oxide, zinc oxide, magnesium oxide, barium carbonate, magnesium silicate, zinc sulfate, barium sulfate, and the combination thereof.

The white pigment is to be blended as a white colorant to heighten brightness, and to improve reflection efficiency of the silicone reflector. The average particle diameter and the shape thereof are also not limited, and an average particle diameter which is a weight average diameter D₅₀ (or median size) in a particle size distribution measurement by laser diffraction analysis is preferably 0.05 to 5.0 μm. These may be used alone or in combination of several kinds. Among the above-mentioned pigments, titanium dioxide is preferred, and a unit lattice of the titanium dioxide may be either a rutile-type, an anatase-type or a brookite-type one.

The above-mentioned titanium dioxide can be previously subjected to surface treatment by a hydrous oxide of Al or Si to increase compatibility or dispersibility with a rein or an inorganic filler.

The titanium dioxide useful in the present invention may be commercially available from Dupont under the trade name of R105, R350 and R 103.

The component c) is present in an amount of from 10% to 50%, preferably from 20% to 40% by weight of the total weight of all components.

### Component d)

In addition, the silicone resin composition for reflector comprises a hydrosilylation catalyst.

According to the present invention, all catalysts which are useful for the addition of Si-bonded hydrogen in the compound of component b) onto the compound of component a) having alkenyl groups can be used as component d).

Examples of such catalysts are compounds or complexes of precious metals comprising platinum, ruthenium, iridium, rhodium and palladium, such as, for example, platinum halides, platinum-olefin complexes, platinum-alcohol complexes, platinum-alcoholate complexes, platinum-ether complexes, platinum-aldehyde complexes, platinum-ketone complexes, including reaction products of H₂PtCl₆.6H₂O and cyclohexanone, platinum-vinylsiloxane complexes, in particular platinum-divinyltetramethyldisiloxane complexes with or without a content of detectable inorganically bonded halogen, bis(γ-picolin)-platinum dichloride, trimethylenedipyridine-platinum dichloride, dicyclopentadiene-platinum dichloride, dimethylsulfoxide ethylene-platinum(Il) dichloride and also reaction products of platinum tetrachloride with olefin and primary amine or secondary amine or primary and secondary amine, such as, for example, the reaction product of platinum tetrachloride dissolved in 1-octene with sec-butylamine. In addition, complexes of iridium with cyclooctadienes, such as, for example, μ-dichlorobis(cyclooctadiene)-diiridium(I), can also be used in the present invention.

Preferably, the hydrosilylation catalyst is a compound or complex of platinum, preferably selected from the group consisting of chloroplatinic acid, allylsiloxane-platinum complex catalyst, supported platinum catalysts, methylvinylsiloxane-platinum complex catalysts, reaction products of dicarbonyldichloroplatinum and 2,4,6-triethyl-2,4,6-trimethylcyclotrisiloxane, platinum divinyltetramethyldisiloxane complex, and the combination thereof, and most preferably platinum-divinyltetramethyldisiloxane complexes.

More preferably, the hydrosilylation catalyst is a methylvinylsiloxane-platinum complex catalyst, and are commercial available for example from the Gelest under the tradename of 6829, 6830, 6831 and 6832 series.

The hydrosilylation catalyst is used in the present invention in an amount of 1 to 500 ppm, and more preferably 2 to 100 ppm, calculated as the elemental precious metal, by weight of the total weight of all components, or in an amount of from 0.2% to 0.33%, preferably from 0.2% to 0.31% by weight of the total weight of all components.

### Component e)

In addition, the silicone resin composition for reflector comprises an inorganic filler.

In the present invention, the component e) is selected from the group consisting of fine powder silica, fine powder alumina, fused silica, crystalline silica, cristobalite, alumina, aluminum silicate, titianium silicate, silicon nitride, aluminum nitride, boron nitride, anitmony trioxide, and combination thereof.

Moreover, it is also possible to use a fibrous inorganic filer such as glass fiber and wollastonite. Among these, fused silica is preferred and are commercially available for example from Denka under the tradename of FB-570, FB-950 or FB-980.

### Additional Components

The silicone resin composition for reflector according to the present invention may optionally comprise additional components selected from the group consisting of a reaction inhibitor, a coupling agent, an antioxidant, a light stabilizer, an adhesion promoter, and combination thereof for further improving the various properties of the silicone resin composition for printing process and/or after curing.

The reaction inhibitor may be selected from the group consisting of the following compounds: 1-ethynyl-1-cyclopentanol; 1-ethynyl-1-cyclohexanol; 1-ethynyl-1-cycloheptanol; 1-ethynyl-1-cyclooctanol; 3-methyl-1-butyn-3-ol; 3-methyl-1-pentyn-3-ol; 3-methyl-1-hexyn-3-ol; 3-methyl-1-heptyn-3-ol; 3-methyl-1-octyn-3-ol; 3-methyl-1-nonyl-3-ol; 3-methyl-1-decyn-3-ol;

3-methyl-1-dodecyn-3-ol; 3-ethyl-1-pentyn-3-ol; 3-ethyl-1-hexyn-3-ol; 3-ethyl-1-heptyn-3-ol; 3-butyn-2-ol; 1-pentyn-3-ol; 1-hexyn-3-ol; 1-heptyn-3-ol; 5-methyl-1-hexyn-3-ol; 3,5-dimethyl-1-hexyn-3-ol; 3-isobutyl-5-methyl-1-hexyn-3-ol; 3,4,4-trimethyl-1-pentyn-3-ol; 3-ethyl-5-methyl-1-heptyn-3-ol; 4-ethyl-1-octyn-3-ol; 3,7,11-trimethyl-1-dodecyn-3-ol; 1,1-diphenyl-2-propyn-1-ol and 9-ethynyl-9-fluorenol. Preferred is 3,5-dimethyl-1-hexyn-3-ol, which is commercially available from TCI. If present, the reaction inhibitor is comprised in an amount of from 0.2% to 0.35%, by weight of the total weight of all components.

Examples of the coupling agent which can be used in the present invention include γ-mercaptopropyl trimethoxysilane; N-β(aminoethyl) γ-aminopropylmethyl dimethoxysilane, N-β(aminoethyl) γ-aminopropyl trimethoxysilane, N-β(aminoethyl) γ-aminopropyl triethoxysilane, γ-aminopropyl trimethoxysilane, γ-aminopropyl triethoxysilane, and N-phenyl-γ-aminopropyl trimethoxysilane; and γ-glycidoxypropyl trimethoxysilane, γ-glycidoxypropylmethyl diethoxysilane, γ-glycidoxypropyl triethoxysilane, and β-(3,4-epoxycyclohexyl)ethyl trimethoxysilane. Such coupling agents are commercially available for example from GE under the trade name of A-186 or A-187. If present, the coupling agent is comprised in an amount of from 0.1% to 2.0%, by weight of the total weight of all components.

In one embodiment, the present invention provides a silicone resin composition for reflector, comprising:
a) 18% to 35% by weight of a silicone resin containing at least two alkenyl groups reactive with a Si—H group per molecule,
b) 1.5% to 2.7% by weight of a silicone resin containing at least two Si—H groups per molecule,
c) 1% to 50% by weight of a white pigment,
d) 0.2% to 0.33% by weight of a hydrosilylation catalyst, and
e) 32% to 48% by weight of an inorganic filler,
in which the weight percentages are based on the total weights of all components of the silicone resin composition for reflector.

The silicone resin composition for reflector can be prepared by mixing all components by a vacuum mixer and/or a three roll mill.

According to the present invention, the silicone resin composition for reflector preferably exhibits a thixotropic index represented by the ratio of the viscosity measured at a shearing rate of 2 s⁻¹ to the viscosity measured at a shearing rate of 20 s⁻¹ in the range of from 2.2 to 3.9, preferably from 2.4 to 3.8. The viscosity is measured on an AR 2000 ex instrument from TA company with equilibrating for 2 min before testing.

Accordingly, the silicone resin composition for reflector possesses an excellent thixotropic property for the printing process in step b) of the manufacturing method according to the present invention. If the thixotropic index is lower than 2.2, the silicone resin composition may have reduced printing capability and/or performance. For example, it may be difficult to press the silicone resin composition through the screen printing mask. If the thixotropic index is larger than 3.9, the silicone resin composition may induce procedural faults. For example, the resin may bleed out or flow to unintended areas of the substrate unit after the printing process.

According to the present invention, the silicone resin composition for reflector preferably exhibits an excellent reflectance of larger than 90%, more preferably larger than 95%, measured on Lambda 35, from Perkin Elmer at a wavelength range of 300 to 800 nm.

The present disclosure may be better understood with reference to the following examples.

### EXAMPLES

### 1. Silicone Resin Compositions for Reflector Materials:

The commercial resources of the components for the silicone resin composition are listed as follows.

| | |
|---|---|
| silicone resin containing at least two | VQM 0.6 (AB Specialty Silicones) |
| alkenyl group | |
| silicone resin containing at least two | Syl-Off 7672 (Dow Corning) |
| Si—H group | |
| hydrosilylation catalyst | SiP 6832.2 (Gelest) |
| reaction inhibitor | 3,5-Dimethyl-1-hexyn-3-ol (TCI) |
| inorganic filler | FB570 (Denka) |
| white pigment | R105 (Dupont) |
| coupling agent | A-186 (GE) |

The Inventive Examples 1 to 3 (E1 to E3) and Comparative Examples 1 and 2 (CE1 and CE2) having the compositions as shown in Table 1 below were prepared by the following procedure: weighing all of the components into a 100 mL polystyrene bottle; adding the mixture into a high speed centrifugal machine under vacuum, and mixing at a rotation speed of 2000 r/min for 5 min; removing the mixture and passing through a three roller mill for 3 runs; adding the mixture into a high speed centrifugal machine under vacuum again, and mixing at a rotation speed of 2000 r/min for 5 min.

TABLE 1
The compositions of the silicone resin for reflector (in parts by weight)

| Component | E1 | E2 | E3 | CE1 | CE2 |
|---|---|---|---|---|---|
| silicone resin | 23.22 | 27.86 | 32.50 | 35.8 | 17.5 |
| containing at | | | | | |
| least two | | | | | |
| alkenyl group | | | | | |
| silicone resin | 1.78 | 2.14 | 2.50 | 2.74 | 1.34 |
| containing at | | | | | |
| least two Si—H | | | | | |
| group | | | | | |
| hydrosilylation | 0.22 | 0.27 | 0.31 | 0.35 | 0.18 |
| catalyst | | | | | |
| reaction | 0.24 | 0.28 | 0.33 | 0.36 | 0.20 |
| inhibitor | | | | | |
| inorganic filler | 45 | 40 | 35 | 30 | 50 |
| white pigment | 30 | 30 | 30 | 30 | 30 |
| coupling agent | 0.8 | 0.8 | 0.8 | 0.8 | 0.8 |

All examples of the silicone resin compositions were tested for the thixotropic index (TI), which indicates the thixotropic property of the compositions. The TI was calculated by dividing the viscosity measured at a shearing rate of 2 s⁻¹ by the viscosity measured at a shearing rate of 20 s⁻¹. The viscosity was measured on an AR 2000 ex instrument from TA Company with equilibrating for 2 min before testing.

In addition, the reflectance of each example after curing according to step c) of the manufacturing method in the present invention were measured on Lambda 35, manufactured by Perkin Elmer at a wavelength range of 460 nm.

The results of measurement of viscosity, TI and reflectance are summarized in Table 2.

TABLE 2
Results of measurement

| Property | E1 | E2 | E3 | CE1 | CE2 |
|---|---|---|---|---|---|
| Viscosity (2 s⁻¹) (Pa · s) | 62.54 | 33.84 | 14.54 | 4.87 | 90.63 |
| Viscosity (20 s⁻¹) (Pa · s) | 19.16 | 9.31 | 4.87 | 2.41 | 22.52 |
| TI | 3.26 | 3.64 | 2.99 | 2.02 | 4.02 |
| Reflectance (460 nm) | 98.1 | 96.7 | 96.5 | 96.2 | N/A¹ |

¹Not tested due to the failure of obtaining a flat surface for testing caused by a high viscosity of the example.

As can be seen, all of the examples E1 to E3 exhibited a suitable thixotropic index and viscosity for a printing process. However, comparative examples CE1 had a lower viscosity and TI that will result in resin spreading after printing and bleed out onto the unintended area of the substrate unit. The composition of CE2 had an overly high viscosity that rendered it difficult to press through the mask during the printing process.

In addition, the reflectors produced from all of the inventive examples exhibited a high reflectance after curing of larger than 96%, which is suitable for the using in an optical semiconductor device.

### 2. Manufacturing Method for an Optical Semiconductor Device Inventive Example

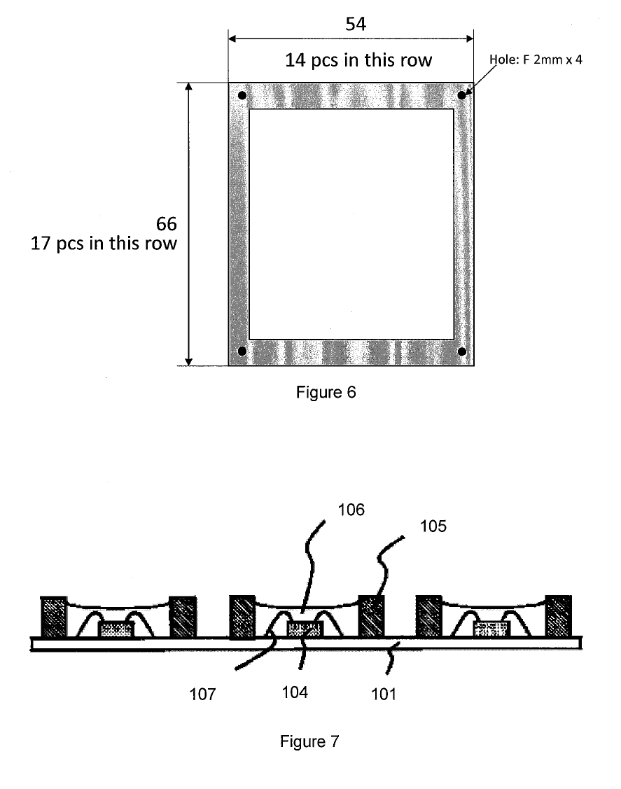

The composition of E1 was used as the silicone resin composition for reflector in the manufacturing method according to the present invention which is shown as follows.
(1) As shown in FIG. 1, a screen printing mask (a) having two through holes (e) was covered on ceramic substrate (b) having a circuit (not shown) formed thereon. Each substrate unit (b) was aligned with the array of through holes (e). As shown in FIG. 6, the substrate has a dimension of 54 mm wide and 66 mm long, including an outer frame. The substrate array is composed of 14 lines and 17 columns of units, i.e. a 14×17 array. Each substrate unit has a dimension of 3 mm in width, 3 mm in length and 0.4 mm in height. The silicone resin of E1 (c) was dispensed on the screen printing mask (a), and squeezed by a spatula (d). As such, each through hole was filled with silicone resin (c), and the silicone resin (c) was screen printed onto each substrate unit (b). Then, the printing screen mask (a) was removed, and thus an array of cavities generated between the printed resins on each substrate unit (b). Then, the printed resin was cured at 150° C. for 1hr in an oven, and reflectors each having a height of 0.4 mm was produced.
(2) As shown in FIG. 2, a LED flip chip (f) having a size of 1 mm in width and 1 mm in length was attached to the circle (not shown) on the substrate unit in each cavity. A silicone encapsulant (g) substantially containing a dimethyl silicone commercially available from ShinEtsu under the trade name of KER-2500, and also containing a filler and phosphor was dispensed into the cavity to the extent that the top surface of the encapsulant layer was not above the top surface of the reflector, and meanwhile the LED chip (f) was completely encapsulated. Then, the silicone encapsulant (g) was cured at 150° C. for 5 hr in an oven.
(3) As shown in FIG. 3, the array of LED devices was diced by applying a rotating blade to cut through in the middle of each reflector. The obtained individual LED devices were further cleaned and dried.

### Comparative Example

In the comparative example, the manufacturing method is the same as that used in the inventive example, except that a conventional manufacturing method by partially molding is applied, and there is a clearance having 1 mm wide between every two neighbouring through reflectors as shown in FIG. 7. As such, the substrate having the same total size as that in the inventive example is composed of a 11×13 array. In addition, the array of LED devices was diced by applying a rotating blade to cut through the substrate in the middle of each clearance.

By the above manufacturing method of a LED device, the number of LED devices thus produced is 238 pieces (14×17=238), which is about 1.7 times more than the number of the LED devices (11×13=143) manufactured by the conventional method. Therefore, it has been demonstrated that by using the manufacturing method according to the present invention, the productivity in the manufacturing of the LED devices was significantly increased compared to the conventional method.

These and other modifications and variations of the present invention may be practiced by those of ordinary skill in the art, without departing from the spirit and scope of the present invention. In addition, it should be understood that aspects of the various embodiments may be interchanged both in whole or in component. Furthermore, those of ordinary skill in the art will appreciate that the foregoing description is by way of example only, and is not intended to limit the invention so further described in such appended claims.

What is claimed is:

1. A method for manufacturing an optical semiconductor device, comprising the steps of:
1) providing a substrate consisting of more than one substrate unit, each substrate unit having an electrical circuit;
2) providing a silicone resin composition on each substrate unit using a printing process;
3) curing the silicone resin composition to form a reflector which defines a cavity on each substrate unit;
4) attaching an optical semiconductor chip on each substrate unit in each cavity and electrically connecting each optical semiconductor chip to the substrate unit;
5) disposing an encapsulant in each cavity and curing the disposed encapsulant to obtain a plurality of joined optical semiconductor devices; and
6) dicing the joined optical semiconductor devices to obtain a plurality of separated optical semiconductor devices.

2. The method according to claim 1, wherein in step 2), the printing process is selected from screen printing, stencil printing and offset printing.

3. The method according to any of claim 1, wherein in step 3), the silicone resin composition for reflector is cured at a temperature of from 120 to 180° C. for 10 minutes to 2 hours.

4. The method according to any of claim 1, wherein in step 3), the reflector has a light reflectance of more than 70% at the wavelength from 350 nm to 800 nm.

5. The method according to any of claim 1, wherein in step 3), the height of the reflector is in the range of from 0.1 mm to 3.0 mm.

6. The method according to any of claim 1, wherein in step 5), the encapsulant comprises silicone resin, filler and phosphor.

7. The method according to any of claim 1, wherein in step 5), the encapsulant is cured at a temperature of from 120 to 180° C. for 1 to 10 hours.

8. A silicone resin composition for reflector, comprising:
a) 18% to 35% by weight of a silicone resin containing at least two alkenyl groups reactive with a Si—H group per molecule,
b) 1.5% to 2.7% by weight of a silicone resin containing at least two Si—H groups per molecule,
c) 1% to 50% by weight of a white pigment,
d) 0.2% to 0.33% by weight of a hydrosilylation catalyst, and
e) 32% to 48% by weight of an inorganic filler,
wherein the weight percentages are based on the total weights of all components of the silicone resin composition for reflector.

9. The silicone resin composition for reflector according to claim 8, wherein the component a) is represented by the average compositional formula (1):
(R¹R²R³SiO_{1/2})ₐ(R⁴R⁵SiO_{2/2})_{b}(R⁶SiO_{3/2})_{c}(SiO_{4/2})_{d} (1),
in which,
R¹ to R⁶ are identical or different groups independently selected from the group consisting of organic groups and an alkenyl group, with the proviso that at least one of R¹ to R⁶ is an alkenyl group,
a represents a number ranging from larger than 0 to less than 1, b, c and d each represent a number ranging from 0 to less than 1, a+b+c+d=1.0, and
the number of alkenyl group per molecule of component a) is at least 2.

10. The silicone resin composition for reflector according to claim 9 wherein the R¹ to R⁶ organic groups in component a) are selected from the group consisting of linear or branched alkyl groups having 1 to 20 carbon atoms, alkenyl groups having 2 to 20 carbon atoms, cycloalkyl groups having 5 to 25 carbon atoms, cycloalkenyl groups having 5 to 25 carbon atoms, aryl groups having 6 to 30 carbon atoms, arylalkyl groups having 7 to 30 carbon atoms and halides thereof.

11. The silicone resin composition for reflector according to claim 9, wherein the R¹ to R⁶ organic groups in component a) are selected from the group consisting of alkyl groups having 1 to 3 carbon atoms and phenyl.

12. The silicone resin composition for reflector according to claim 8, wherein the component b) is represented by the average compositional formula (5):
(R¹R²R³SiO_{1/2})ₐ(R⁴R⁵SiO_{2/2})_{b}(R⁶SiO_{3/2})_{c}(SiO_{4/2})_{d} (5),
in which,
R¹ to R⁶ are identical or different groups independently selected from the group consisting of organic groups and hydrogen atom bonded directly to a silicon atom, with the proviso that at least one of R¹ to R⁶ is a hydrogen atom bonded directly to a silicon atom,
a and d each represent a number ranging from larger than 0 to less than 1, b and c each represent a number ranging from 0 to less than 1, a+b+c+d=1.0, and
the number of hydrogen atom bonded directly to a silicon atom per molecule of the silicone resin is at least 2.

13. The silicone resin composition for reflector according to claim 12, wherein the organic groups in component b) are selected from the group consisting of linear or branched alkyl groups having 1 to 20 carbon atoms, alkenyl groups having 2 to 20 carbon atoms, cycloalkyl groups having 5 to 25 carbon atoms, cycloalkenyl groups having 5 to 25 carbon atoms, aryl groups having 6 to 30 carbon atoms, arylalkyl groups having 7 to 30 carbon atoms and halides thereof.

14. The silicone resin composition for reflector according to claim 12, wherein the organic groups in component b) are selected from the group consisting of alkyl groups having 1 to 3 carbon atoms and phenyl.

15. The silicone resin composition for reflector according to claim 8, wherein the ratio of the viscosity at a shearing rate of 2 s⁻¹ to the viscosity at a shearing rate of 20 s⁻¹ is in the range of from 2.2 to 3.9.

16. An optical semiconductor device manufactured by the method according to claim 1.

17. A light emitting diode device manufactured by the method according to claim 1.
